(19) United States
(12) Patent Application Publication
(10) Pub. No.: US 2010/0013015 A1
(43) Pub. Date: Jan. 21, 2010

(54) METAL SOURCE/DRAIN SCHOTTKY BARRIER SILICON-ON-NOTHING MOSFET DEVICE

(75) Inventor: John P. Snyder, Edina, MN (US)

Correspondence Address: LEMAIRE PATENT LAW FIRM, P.L.L.C., P.O. BOX 1818, BURNSVILLE, MN, 55337, US

(73) Assignee: AVOLARE 2, LLC, Chapel Hill, NC (US)

(21) Appl. No.: 12/569,895

(22) Filed: Sep. 29, 2009

Related U.S. Application Data
(63) Continuation of application No. 11/513,894, filed on Aug. 31, 2006, now abandoned.
(60) Provisional application No. 60/712,888, filed on Aug. 31, 2005.

(51) Int. Cl. H01L 29/786

(52) U.S. Cl. 257/347; 257/E29.286

(57) ABSTRACT

A Schottky barrier MOSFET (SB-MOS) device and a method of manufacturing having a silicon-on-nothing (SON) architecture in a channel region are provided. More specifically, metal source/drain SB-MOS devices are provided in combination with a channel structure comprising a semiconductor channel region such as silicon isolated from a bulk substrate by an SON dielectric layer. In one embodiment, the SON dielectric layer has a triple stack structure comprising oxide on nitride on oxide, which is in contact with the underlying semiconductor substrate.

### CROSS-REFERENCE TO RELATED APPLICATIONS

This application is a continuation application of U.S. patent application Ser. No. 11/513,894, filed Aug. 31, 2006, which claimed the benefit of and priority to U.S. Provisional Patent Application No. 60/712,888, filed Aug. 31, 2005, each of which is incorporated by reference herein in its entirety. This application is also related to U.S. patent application Ser. No. 10/957,913, filed Oct. 4, 2004, which is incorporated by reference herein in its entirety.

### FIELD OF THE INVENTION

The present invention relates to semiconductor devices for regulating the flow of electric current and has specific application to the fabrication of these devices in the context of an integrated circuit (“IC”). More particularly, the present invention relates to a transistor for regulating the flow of electric current having metal source and/or drain forming Schottky or Schottky-like contacts to a channel region.

### BACKGROUND OF THE INVENTION

One type of transistor known in the art is a Schottky-barrier metal oxide semiconductor field effect transistor (“Schottky-barrier MOSFET” or “SBMOS”). As shown in FIG. 1, the SB-MOS device 100 comprises a semiconductor substrate 110 in which a source electrode 120 and a drain electrode 125 are formed, separated by a channel region 140 having channel dopants. The channel region 140 is the current-carrying region of the substrate 110. For purposes of the present invention, the channel region 140 in the semiconductor substrate 110 extends vertically below a gate insulator 150 to a boundary approximately aligned with the bottom edge of the source electrode 120 and bottom edge of the drain electrode 125. The channel dopants have a maximum dopant concentration 115, which is typically below the source 120 and drain 125 electrodes, and thus outside of the channel region 140.

For an SB-MOS device, at least one of the source 120 or the drain 125 electrodes is composed partially or fully of a metal. Because at least one of the source 120 or the drain 125 electrodes is composed in part of a metal, they form Schottky or Schottky-like contacts with the substrate 110 and the channel region 140. A Schottky contact is defined as a contact formed by the intimate contact between a metal and a semiconductor, and a Schottky-like contact is defined as a contact formed by the close proximity of a metal and a semiconductor. The Schottky contacts or Schottky-like contacts or junctions 130, 135 may be provided by forming the source 120 or the drain 125 from a metal silicide. The channel length is defined as the distance from the source 120 electrode to the drain 125 electrode, laterally across the channel region 140.

The Schottky or Schottky-like contacts or junctions 130, 135 are located in an area adjacent to the channel region 140 formed between the source 120 and drain 125. The gate insulator 150 is located on top of the channel region 140. The gate insulator 150 is composed of a material such as silicon dioxide. The channel region 140 extends vertically from the insulating layer 150 to the bottom of the source 120 and drain 125 electrodes. A gate electrode 160 is positioned on top of the insulating layer 150, and a thin insulating layer 170 is provided on the gate electrode 160 sidewalls. The thin insulating layer 170 is also known as the sidewall spacer. The gate electrode 160 may be doped poly silicon and may further include a metal region 165. The source 120 and drain 125 electrodes may extend laterally below the spacer 170 and gate electrode 160. A field oxide 190 electrically isolates devices from one another. An exemplary Schottky-barrier device is disclosed in U.S. Pat. No. 6,303,479, assigned to the same assignee, Spinnaker Semiconductor, Inc.

A fabrication challenge of SB-MOS technology is the precise positioning of the metal silicide Schottky barrier junctions 130,135 at an optimized lateral location in the channel region 140. Preferably, the junctions 130,135 are located at a lateral location in the channel region 140 that is below the gate electrode 160, or not substantially displaced laterally away from the gate electrode 160. The drive current of the SB-MOS device is highly sensitive to positioning of the Schottky barrier junctions 130,135. The electrostatic fields within the channel region 140 of the device change depending on the positioning of the Schottky barrier junctions 130,135. Furthermore, the current emission and therefore drive current is highly sensitive to the magnitude of the electric field at the Schottky barrier junction 130. In summary, as the Schottky barrier junction 130 below the gate oxide moves laterally away from the gate electrode 160, the drive current and device performance decreases rapidly. Generally, it is difficult to control the location of the Schottky barrier junctions 130,135 in the channel region 140 within the constraints of acceptable sidewall spacer 170 thickness and source/drain 120/125 depth.

Accordingly, there is a need in the art for a Schottky barrier MOS fabrication process that controllably sets the position of the Schottky barrier junction in the channel region and for an SB-MOS device that has a well-controlled junction location.

### BRIEF SUMMARY OF THE INVENTION

In one aspect, the present invention provides a device for regulating the flow of electric current, the device having Schottky or Schottky-like source/drain regions in contact with a channel region isolated from the semiconductor substrate by a Silicon-on-Nothing (SON) structure, the device hereafter referred to as SON SB-MOS. In another aspect, the present invention provides a method of fabricating an SON SB-MOS device. In particular, the SON SB-MOS process provides a means to provide controlled positioning of the metal Schottky barrier junction in the channel region of the device. The present invention, in one embodiment, provides an SON dielectric triple stack structure comprising oxide, nitride and oxide, between the semiconductor substrate and the channel region of the device. It further provides an isotropic nitride etch, including a partial lateral overetch to etch the nitride below the gate electrode of the MOSFET device. It then provides an isotropic etch of the oxide, also laterally etching the oxide until the remaining SON triple stack layers are located at approximately the same lateral positions. This novel overetch of the SON dielectric layers provides a means to expose the bottom surface of the silicon channel region. Then, upon deposition of metal and annealing, suicide forms in the channel region, growing upward from the exposed bottom surface of the silicon channel, as well as laterally from the silicon channel sidewall. Silicide is also formed below the SON dielectric layers. This process produces a device having improved SB-MOS manufacturability and performance, as compared to the prior art.

While multiple embodiments, are disclosed, still other embodiments of the present invention will become apparent to those skilled in the art from the following detailed description, which shows and describes illustrative embodiments of the invention. As it will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 illustrates a sectional view of an existing Schottky-barrier metal oxide semiconductor field effect transistor (“Schottky barrier MOSFET” or “SB-MOS”).

FIG. 2 illustrates an exemplary process using implantation of the semiconductor substrate, selective SiGe epitaxial layer growth and selective Si epitaxial layer growth, in accordance with the principles of the present invention.

FIG. 3 illustrates an exemplary process using patterning a silicon film on a thin gate insulator, formation of thin insulating sidewall spacers, and self-aligned source/drain region etching, in accordance with the principles of the present invention.

FIG. 4 illustrates an exemplary process using selective lateral SiGe etching to provide a tunnel void region and filling the tunnel void region with a thermally grown and/or a deposited oxide layer and a thin nitride layer, in accordance with the principles of the present invention.

FIG. 5 illustrates an exemplary process using an isotropic nitride etch, in accordance with the principles of the present invention.

FIG. 6 illustrates an exemplary process using an isotropic oxide etch, in accordance with the principles of the present invention.

FIG. 7 illustrates an exemplary embodiment of a process using PVD to deposit a metal covering all surfaces and filling the region below the gate sidewall spacer and the gate electrode.

FIG. 8 illustrates an exemplary embodiment of a silicide anneal and metal strip to form an SON SB-MOS device, in accordance with the principles of the present invention.

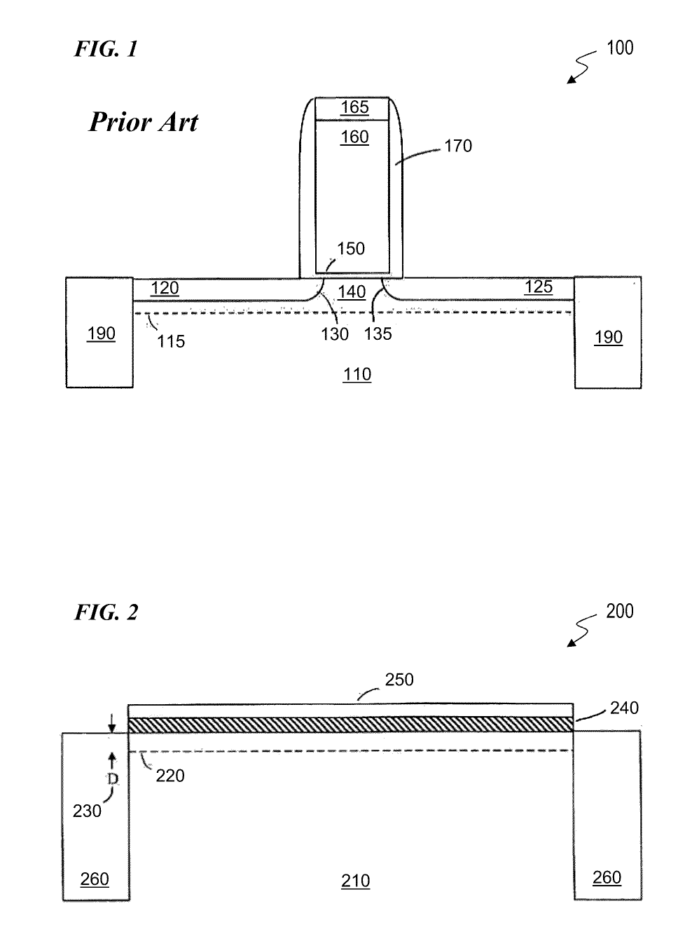

### DETAILED DESCRIPTION

In general, an SB-MOS device and method of fabrication of the device is provided. In one embodiment of the present invention, a method of fabricating an SON SB-MOS device includes providing a semiconductor substrate and doping the semiconductor substrate and channel region. The method further includes forming a selective SiGe epitaxial layer followed by a selective Si epitaxial layer. The method further includes providing a gate electrode comprising a thin gate insulator, a gate electrode material such as metal or polysilicon, and thin insulating sidewall spacers surrounding the gate electrode. The method further includes etching the source/drain regions followed by selective lateral SiGe etching to provide a tunnel void region between the silicon substrate and the epitaxial silicon layer. The method further includes filling the tunnel void region with a thermally grown and/or deposited oxide layer and a thin nitride layer. The method further includes isotropically etching the nitride everywhere using a slight overetch such that the nitride in the tunnel void region is etched laterally. The method further includes removing the oxide by hydrofluoric acid, which as a result exposes a portion of the bottom surface of the epitaxial silicon layer. The method further includes depositing a metal by PVD thereby covering all surfaces and filling the region below the gate sidewall spacer. The method further includes a silicide anneal and a metal strip to form a metal silicide source/drain structure that provides a Schottky or Schottky-like contact with the channel region.

Of particular advantage, in one embodiment, the metal source and drain electrodes provide significantly reduced parasitic series resistance (˜10 Ω-μm) and contact resistance (less than 10⁻⁸ Ω-cm²). The built-in Schottky barrier at the Schottky or Schottky-like contacts provide superior control of off-state leakage current. The device substantially eliminates parasitic bipolar action, making it unconditionally immune to latch-up, snapback effects, and multi-cell soft errors in memory and logic. Elimination of bipolar action also significantly reduces the occurrence of other deleterious effects related to parasitic bipolar action such as single event upsets and single cell soft errors. The device of the present invention is highly manufacturable, generally requiring two fewer masks for source/drain formation, no shallow extension or deep source/drain implants, and a low temperature source/drain formation process. Due to low-temperature processing, integration of new, potentially critical materials such as high K gate insulators, strained silicon and metal gates is made easier.

FIG. 2 shows a silicon substrate 210 that has means for electrically isolating transistors from one another using means such as shallow trench isolation 260. Throughout the discussion herein, there will be examples provided that make reference to a semiconductor substrate on which an SON SB-MOS device is formed. The present invention does not restrict the semiconductor substrate to any particular type. One skilled in the art will readily realize that many semiconductor substrates may be used for SON SB-MOS devices including for example silicon, silicon germanium, gallium arsenide, indium phosphide, strained semiconductor substrates, and silicon on insulator (SOI). These substrate materials and any other semiconductor substrate may be used and are within the scope of the teachings of the present invention.

As shown in FIG. 2, an appropriate channel dopant species is ion-implanted such that a maximum dopant concentration 220 is provided to a predetermined depth D 230 in the silicon. In one embodiment, the channel dopant species is Arsenic for P-type devices and Indium for N-type devices. However, it is appreciated that any other suitable channel dopant species commonly used for P-type or N-type transistor devices can be used in accordance with the principles of the present invention. In another embodiment, the channel dopant concentration profile varies significantly in the vertical direction but is generally constant in the lateral direction. In a further embodiment, the depth D 230 of the maximum dopant concentration is approximately 10 to 200 nm. These doping profiles and concentrations and any other doping profiles and concentrations may be used including no doping and are within the scope of the teachings of the present invention. In one embodiment as further shown in FIG. 2, it is at this step that a new and novel process is employed. A selective SiGe epitaxial layer 240 is formed (˜10-50 nm) followed by a selective Si epitaxial layer 250 (˜10-50 nm). In another embodiment, the selective Si epitaxial layer 250 may be strained.

As shown in FIG. 3, following providing the epitaxial SiGe 240 and Si 250 layers, the process follows a conventional SB-MOS flow up through the formation of the gate electrode. A gate electrode comprising a thin gate insulator 310 and a gate 320 formed from a material such as metal or polysilicon are provided. In another embodiment, the thin gate insulator 310 is comprised of silicon dioxide with a thickness of approximately 6 to 50 Å. In a further embodiment, a material having a high dielectric constant (high K) is provided. Examples of high K materials are those materials having dielectric constants greater than that of silicon dioxide, including for example nitrided silicon dioxide, silicon nitride, and metal oxides such as TiO₂, Al₂O₃, La₂O₃, HfO₂, ZrO₂, CeO₂, Ta₂O₅, WO₃, Y₂O₃, and LaAlO₃, and the like. Using lithographic techniques and a silicon etch, the gate electrode 320 is patterned as shown in the process step 300 illustrated in FIG. 3.

As further shown in FIG. 3, a thin insulator sidewall spacer 330 is provided. In one embodiment, the sidewall spacer 330 is a thermally grown oxide that has a thickness of approximately 50 to 500 Å. In another embodiment, the thermally grown sidewall spacer 330 is provided by a rapid thermal oxidation (RTO) process having a maximum temperature of 900 to 1200° C. for a dwell time of 0.0 to 60 seconds. One skilled in the art will readily realize that there are many manufacturing methods for providing thin insulators such as by growth by thermal oxidation or by deposition. One skilled in the art will further realize that other materials may be used for the sidewall spacer 330, such as nitrides or other high K insulating materials, and that the sidewall spacer 330 may be comprised of multiple insulator materials. Using the sidewall spacer and gate electrode as a mask, and by using one or more anisotropic etches to remove the insulator layer or layers formed on the horizontal surfaces when forming the sidewall spacer 330, and to further remove the epitaxial Silicon layer 250 and the epitaxial SiGe layer 240 in the source/drain regions, the horizontal surfaces 340,350 are exposed while preserving the insulator layer sidewall spacer 330 on the vertical surfaces. In this way, a sidewall spacer 330 is formed.

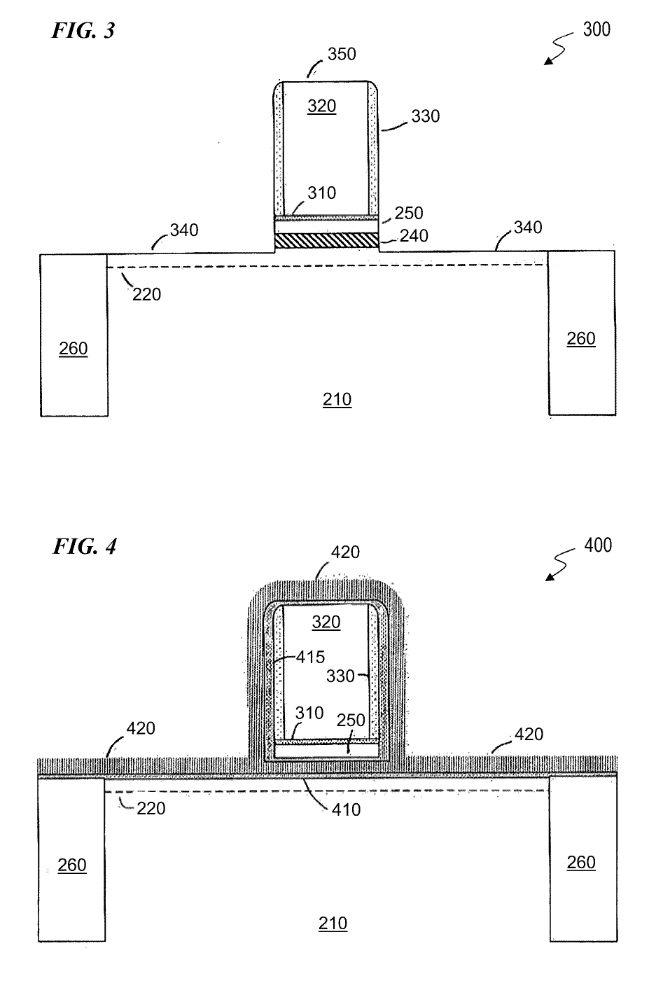

A selective lateral SiGe etch is provided next, which removes the SiGe layer 240, thereby providing a tunnel void region between the silicon substrate 210 and the epitaxial silicon layer 250. The epitaxial Si layer 250 will become the channel region of the device, and so hereafter the term channel region is also labeled as element 250. As shown in FIG. 4, the tunnel void region is then filled with an oxide layer 410 formed on the semiconductor substrate 210, an oxide layer 415 formed around the gate electrode, and a nitride layer formed on, in-between, and around the oxide layers 410, 415. The oxide layers 410 and 415 are generally provided simultaneously in the same process step. In one embodiment, the oxide layers 410, 415 are deposited by a CVD high temperature oxidation (HTO) process. In another embodiment, the oxide layers 410, 415 are thermally grown by a rapid thermal oxidation (RTO) process. In yet another embodiment, the oxide layers 410, 415 are provided by first an HTO process and second an RTO process. In yet another embodiment, the oxide layers 410, 415 are provided by first an RTO process and second an HTO process. These and any other techniques for providing the thin oxide layers 410, 415 can be used within the scope of the present invention. The nitride 420 is provided by a CVD nitride process that deposits a pure nitride Si₃N₄ layer or any other nitride compound such oxynitrides. The tunnel void region is therefore completely filled by a triple stack of oxide 410-nitride 420-oxide 415, as shown in process step 400 in FIG. 4.

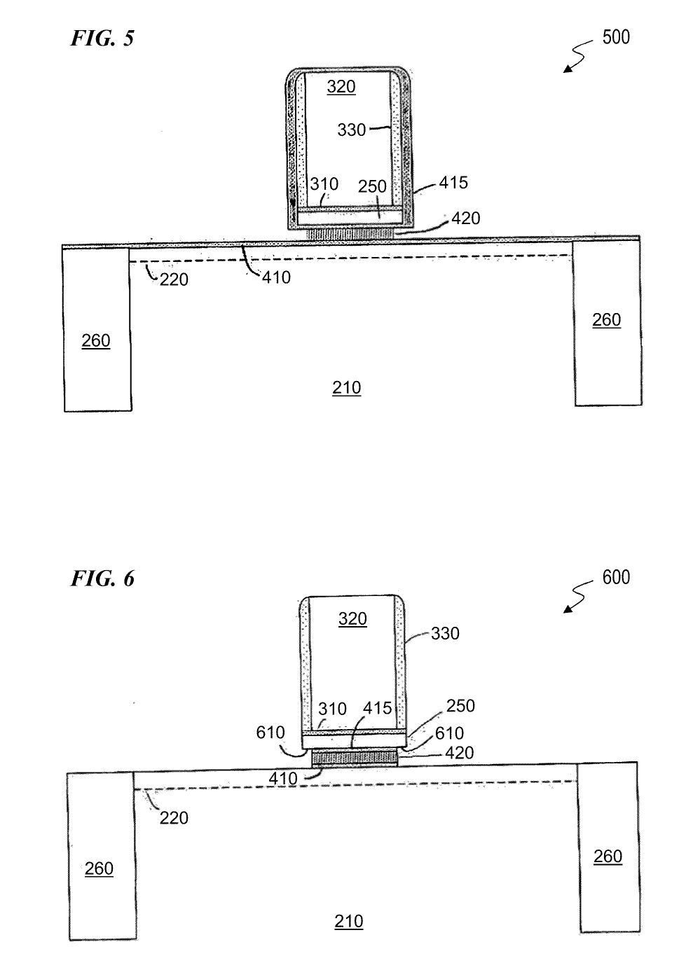

As shown in FIG. 5, the nitride layer 420 is next etched everywhere using an isotropic etch. In one embodiment, the isotropic nitride etch is a plasma etch. A slight overetch is used so that the nitride in the tunnel void region is etched laterally. Then, as shown in FIG. 6, the remaining oxide layers 410, 415 are removed by a hydrofluoric acid etch. As a result, a portion of the bottom surface 610 of the epitaxial silicon layer 250 is exposed and a triple stack of oxide (410)-nitride (420)-oxide (415) is formed below the gate electrode 320.

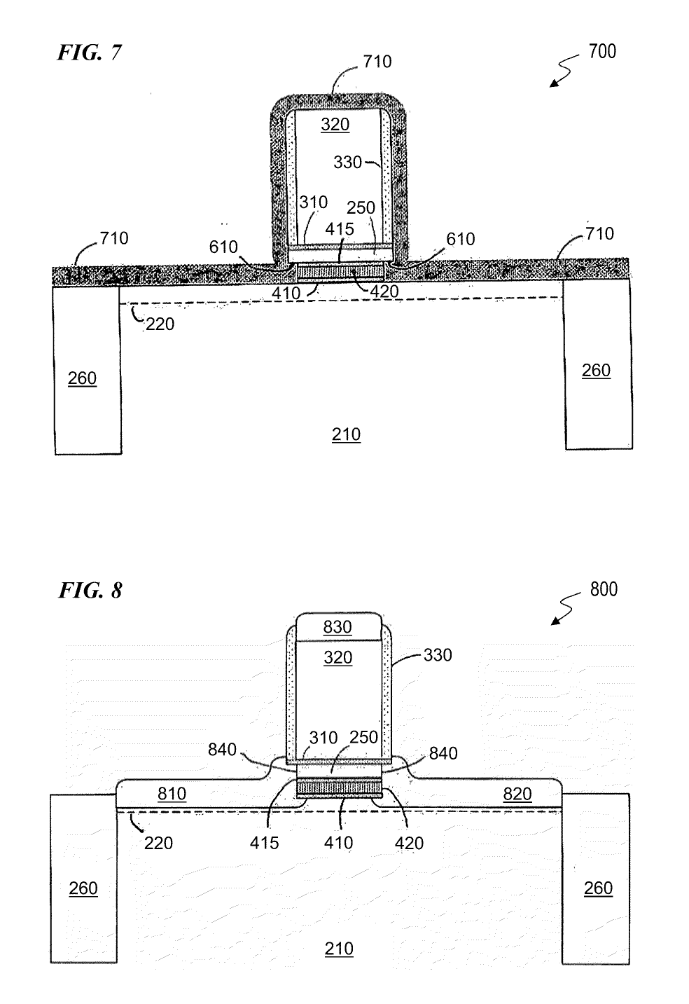

As shown in FIG. 7, the next step encompasses depositing an appropriate metal as a blanket film 710 on all exposed surfaces and filling the empty region below the sidewall spacer 330 and the gate electrode 320. Deposition may be provided by either a sputter (PVD) or evaporation process or more generally any thin film metal deposition process. In one embodiment, the substrate 210 is heated during metal deposition to encourage diffusion of the impinging metal atoms to the exposed silicon surface 610 below the epitaxial silicon layer 250. In one embodiment, the metal is approximately 250 Å thick, but more generally approximately 50 Å to 1000 Å thick.

As shown in FIG. 8, the wafer is then annealed for a specified time at a specified temperature so that, at all places where the metal is in direct contact with the silicon, a chemical reaction takes place that converts the metal to a metal silicide 810, 820, 830. In one embodiment, for example, the wafer is annealed at about 400° C. for about 45 minutes or more generally approximately 300 to 700° C. for approximately 1 to 120 min. The metal that was in direct contact with a non-silicon surface such as the gate sidewall spacer 330 is left unreacted.

A wet chemical etch is then used to remove the unreacted metal while leaving the metal-silicide untouched. In one embodiment, aqua regia is used to remove Platinum and HNO₃ is used to remove Erbium. It is appreciated that any other suitable etch chemistries commonly used for the purpose of etching Platinum or Erbium, or any other suitable metal systems used to form Schottky or Schottky-like contacts can be used within the scope of the present invention. In one embodiment, one or more additional anneals may be performed following the removal of the unreacted metal. The SON SB-MOS device is now complete and ready for electrical contacting to gate 830, source 810, and drain 820, as shown in the process step 800 illustrated in FIG. 8.

As a result of this exemplary process, Schottky or Schottky-like contacts are formed to the channel region 250 and substrate 210 respectively wherein the Schottky contacts are located at a position controlled by the SON process. In one embodiment, the interface 840 of the source 810 and drain 820 electrodes to the channel region 250 is generally aligned with the edge of the vertical sides of the gate electrodes 320 or is located below the gate electrode 320 (“Overlapped source/drain”). In another embodiment, a gap is formed between the interface 840 of the source 810 and drain 820 electrodes to the channel region 250 and the edge of the vertical sides of the gate electrode 320 (“Non-overlapped source/drain”).

While traditional Schottky contacts are abrupt, the present invention specifically anticipates that in some circumstances an interfacial layer may be utilized between the metal source/drain 810/820 and the channel region 250 and/or the substrate 210. These interfacial layers may be ultra-thin, having a thickness of approximately 10 nm or less. Thus, the present invention specifically anticipates Schottky-like contacts and their equivalents to be useful in implementing the present invention. Furthermore, the interfacial layer may comprise materials that have conductive, semi-conductive, and/or insulator-like properties. For example, ultra-thin interfacial layers of oxide or nitride insulators may be used, ultra-thin dopant layers formed by dopant segregation techniques may be used, or ultra-thin interfacial layers of a semiconductor, such as Germanium, may be used to form Schottky-like contacts, among others.

Throughout the discussion herein there will be examples provided that make reference to Schottky and Schottky-like barriers and contacts in regards to IC fabrication. The present invention does not recognize any limitations in regards to what types of Schottky interfaces may be used in affecting the scope of the present invention. Thus, the present invention specifically anticipates these types of contacts to be created with any form of conductive material or alloy. For example, for the P-type device, the metal source and drain 810,820 may be formed from any one or a combination of Platinum Silicide, Palladium Silicide, or Iridium Silicide. For the N-type device, the metal source and drain 810,820 may be formed from a material from the group comprising Rare Earth Silicides such as Erbium Silicide, Dysprosium Silicide or Ytterbium Silicide, or combinations thereof. It is appreciated that any other suitable metals commonly used at the transistor level, such as titanium, cobalt and the like, can be used as well as a plethora of more exotic metals and other alloys. In another embodiment, the silicided source/drain can be made of multiple layers of metal silicide, in which case other exemplary silicides, such as titanium silicide or tungsten silicide for example, may be used.

Generally, an SB-MOS device is designed to have overlapped source/drains or non-overlapped source/drains. Overlapped source/drain SBMOS devices can be difficult to fabricate because of limitations on sidewall spacer thickness, deposition thickness of the metal used to form the source/drain regions, and limitations in the characteristics of the silicide formation process for certain silicide materials. Overlapped source/drain SB-MOS devices are more easily achieved if the metal silicide is grown from the bottom interface 610 of the epitaxial silicon layer 250, which is possible by employing the teachings of the present invention SON SB-MOS process teachings. The metal silicide growth front extends laterally into the channel region 250 as it grows up from the bottom interface 610 of the epitaxial silicon layer 250, as shown in FIG. 7 and FIG. 8. Furthermore, the metal silicide also forms slightly below the SON dielectric layers 410, 420, 415 below the channel region 250. The initial doping 220 prevents leakage from the source/drain contacts located below the SON dielectric layers 410,420. The doping profile in the region between the source/drain is generally laterally uniform, although other profiles could be used that are laterally non-uniform, or no doping could be used.

Two factors that determine the final location of the Schottky barrier junction 840 with the channel region 250 are the pre-silicide nitride and oxide lateral etches in process steps 500 and 600, and the thickness of the deposited metal layer 710 in process step 700. By varying the nitride and oxide etch processes, the extent of exposure of the bottom interface 610 of the silicon layer 250 is controlled. This affects the final location of the source/drain 810,820 junction 840 to the channel region 250. This enables improved control of lateral positioning of the post-silicide Schottky barrier junction location 840 in the channel region 250.

As shown in FIG. 8, the resulting device from the exemplary process shown in FIGS. 2-8 is a metal source/drain SON SB-MOS device having an SON dielectric structure interposed between the silicon channel region 250 and the semiconductor substrate 210.

The SON SB-MOS process and device architecture of the present invention enables the use of gate materials having work function similar to N+ or P+ polysilicon for SON NMOS or PMOS devices respectively, thereby enabling use of low Vₜ gate electrodes, while maintaining reasonably good on-off current ratios and improving the drive current performance of the SON device. Due to the presence of the built-in Schottky barrier at the junction 840 of the metal and semiconductor channel region, off-state leakage current will be significantly reduced compared to an SON device having doped source/drains and a gate with N+ or P+ polysilicon. Furthermore, SON SB-MOS technology enables a relatively simple manufacturing process for forming the source/drain region of an SON device. Because the source and drain are metal, they also eliminate a parasitic source/drain resistance problem that in many cases degrades the performance of SON MOSFET technology. SON SB-MOS also simplifies the conventional SON process flow by eliminating at least one selective silicon epitaxy step and simplifying the sidewall spacer process as well.

From the point of view of the SB-MOS device, the SON dielectric layers 410, 415, 420 significantly reduce the source/drain off-state leakage of an otherwise undoped SB-MOS device. Compared to a doped channel SB-MOS device of similar off-state leakage current, the present invention provides a channel region with virtually no doping in the epitaxial silicon channel region 250, thereby significantly improving the charge carrier effective mobility and device performance. Furthermore, the process described above enables the precise lateral placement of the silicide source/drain junctions, which is essential for optimizing SB-MOS device performance.

One of the important performance characteristics for SB-MOS devices is the drive current (I_{d}), which is the electrical current from source to drain when the applied source voltage (Vₛ) is grounded, and the gate voltage (V_{g}) and drain voltage (V_{d}) are biased at the supply voltage (V_{dd}). Another important performance characteristic for SB-MOS devices is the total gate capacitance (C_{g}), which is determined by various capacitances such as that due to gate insulator 310, the fringing field capacitance and the overlap capacitance. Drive current and total gate capacitance are two of the important parameters that determine circuit performance. For example, the switching speed of a transistor scales as I_{d}/C_{g} so that higher drive current devices and lower total gate capacitance devices switch faster, thereby providing higher performance integrated circuits. There are many variables that can affect the drive current and total gate capacitance of an SB-MOS device, including for example, the lateral location of the Schottky or Schottky-like contact 840 in relation to the edge of the gate electrode 320.

In an SB-MOS device, the drive current, which is generally determined by the tunneling current density (J_{SB}) through the Schottky barrier into the channel, is controlled by the gate induced electric field (Eₛ) located at the interface 840 of the source 810 and the channel region 250. As the voltage applied to the gate (V_{g}) is increased, E_{S} will also increase. Increasing E_{S} modifies the band diagram in the region near the junction 840 such that J_{SB} increases generally exponentially with Eₛ (Equation 1)

$${J}_{SB} = A {e}^{( - \frac{B}{{E}_{s}} )} \qquad ( 1 )$$

where A and B are generally constants.

In addition to V_{g}, E_{S} is also strongly affected by the Schottky barrier-channel region junction 840 proximity to the edge of the gate electrode 320. When junction 840 is not located below the gate electrode 320 such as when non-overlapped source/drains are used, E_{S} and therefore J_{SB} and I_{d} decrease substantially and continue to decrease as the junction 840 moves further laterally away from the edge of the gate electrode 320. Accordingly, the present invention provides a method of fabricating an SB-MOS device that allows the placement of the Schottky or Schottky-like source and drain junction 840 to be accurately controlled with respect to the gate electrode by using the SON process. The present invention process provides a means to maximize the electric field Eₛ and drive current I_{d} and optimize device performance.

In regards to total gate capacitance C_{g}, the optimal location of the junction 840 in relation to the edge of the gate electrode 320 is a function of device design and performance requirements. In particular, the total gate capacitance C_{g} will decrease as the distance between the junction 840 and the edge of the gate electrode 320 increases, while, as noted above, the drive current I_{d} will simultaneously decrease. Performance optimization will require tradeoffs in drive current I_{d} and total gate capacitance C_{g}, which can be more controllably provided by the teachings of the present invention. For example, by using the process teachings of the present invention, the location of the junction 840 in relation to the edge of the gate electrode 320 can be provided such that the tradeoffs in gate capacitance C_{g} and drive current I_{d} are optimized.

By using the techniques of the present invention, several benefits occur including, but not limited to the following. The present invention process provides additional fabrication control of the precise location of the Schottky or Schottky-like junction placement below the gate electrode in the channel region. The resulting Schottky or Schottky-like junction position can therefore be controllably placed at a lateral position below the gate electrode to maximize drive current, minimize total gate capacitance and optimize device performance.

The present invention is particularly suitable for use in situations where short channel length MOSFETs are to be fabricated, especially in the range of channel lengths less than 100 nm. However, nothing in the teachings of the present invention limits application of the teachings of the present invention to these short channel length devices. Advantageous use of the teachings of the present invention may be had with channel lengths of any dimension.

Although the present invention has been described with reference to preferred embodiments, persons skilled in the art will recognize that changes may be made in form and detail without departing from the spirit and scope of the invention. While the present invention is particularly suitable for use with SBMOS semiconductor devices, it may also be applied to other semiconductor devices. Thus, while this specification describes a fabrication process for use with SB-MOS devices, this term should be interpreted broadly to include any device for regulating the flow of electrical current having a conducting channel that has two or more points of electrical contact wherein at least one of the electrical contacts is a Schottky or Schottky-like contact.

What is claimed are:

1. A device for regulating a flow of electric current, the device comprising:
a semiconductor substrate;
a gate structure;
a semiconducting channel region;
an insulating region between the semiconducting channel region and the semiconductor substrate;
a source electrode and a drain electrode each in contact with the semiconductor substrate, wherein the source electrode is in contact with one end of the semiconducting channel region and the drain electrode is in contact with an opposite end of the semiconducting channel region, and wherein at least one of the source electrode and the drain electrode forms a Schottky or Schottky-like contact with the semiconducting channel region; and
wherein the insulating region is further bounded between the source electrode and the drain electrode.

2. The device of claim 1 wherein the insulating region is comprised of a first insulating layer of a first type, a second insulating layer of a second type, and a third insulating layer of the first type.

3. The device of claim 2 wherein the first insulating layer of the first type is an oxide and the third insulating layer of the first type is an oxide.

4. The device of claim 2 wherein the second insulating layer of the second type is a nitride.

5. The device of claim 1 wherein the source electrode and the drain electrode are formed from a member of the group consisting of: Platinum Silicide, Palladium Silicide and Iridium Silicide.

6. The device of claim 1 wherein the source electrode and the drain electrode are formed from a member of the group consisting of the rare-earth silicides.

7. The device of claim 1 wherein at least one of the source or drain electrodes forms a Schottky or Schottky-like contact at least in areas adjacent to the semiconducting channel region.

8. The device of claim 1 wherein the semiconducting channel region is strained.

9. The device of claim 1 wherein the semiconductor substrate is silicon.

10. The device of claim 1 wherein the gate structure includes:
a gate insulating layer in contact with the channel region;
a gate electrode in contact with the gate insulating layer; and
an insulating sidewall spacer that covers at least one side of the gate electrode.

11. The device of claim 10 wherein the gate insulating layer includes silicon dioxide.

12. The device of claim 10 wherein the gate insulating layer includes a high-dielectric-constant material.

13. The device of claim 12 wherein the high-dielectric-constant material is chosen from the group consisting of nitrided silicon dioxide, silicon nitride, TiO₂, Al₂O₃, La₂O₃, HfO₂, ZrO₂, CeO₂, Ta₂O₅, WO₃, Y₂O₃, and LaAlO₃.

14. The device of claim 10 wherein the gate electrode includes polysilicon.

15. The device of claim 10 wherein the gate electrode includes a metal.

16. The device of claim 10 wherein the insulating sidewall spacer includes silicon dioxide.

17. The device of claim 1 wherein the semiconducting channel region includes channel doping having a channel dopant concentration profile.

18. The device of claim 17 wherein the channel dopant concentration profile varies significantly in direction perpendicular to a major face of the gate insulator but is substantially constant in a direction that is parallel to the major face of the gate insulator.

19. The device of claim 17 wherein the channel doping is chosen from the group consisting of arsenic and indium.

20. An apparatus comprising:
a semiconductor substrate;
a semiconducting channel region;
a source electrode and a drain electrode each in contact with the semiconductor substrate, wherein the source electrode is in contact with one end of the semiconducting channel region and the drain electrode is in contact with an opposite end of the semiconducting channel region, and wherein at least one of the source electrode and the drain electrode forms a Schottky or Schottky-like contact with the semiconducting channel region;
means for insulating the semiconducting channel region from the semiconductor substrate; wherein the means for insulating is bounded between the source electrode and the drain electrode; and
a gate structure formed along a surface of the semiconducting channel region opposite the means for insulating.
